(19) United States
(12) Patent Application Publication
(10) Pub. No.: US 2012/0138138 A1
(43) Pub. Date: Jun. 7, 2012

(54) Solar cells with back side contacting and also method for production thereof

(75) Inventors: Filip Granek, Wrockaw (PL); Daniel Kray, Freiburg (DE); Kuno Mayer, Frankfurt/Main (DE); Monica Aleman, Brussels (DE); Sybille Hopman, Mahlberg (DE)

(73) Assignee: Fraunhofer-Gesellschaft zur Forderung der angewandten Forschung e.V., Munchen (DE)

(21) Appl. No.: 13/254,181

(22) PCT Filed: Feb. 22, 2010
(86) PCT No.: PCT/EP2010/001152

§ 371 Date: Feb. 21, 2012

(30) Foreign Application Priority Data
Mar. 2, 2009 (DE) 10 2009 011 305.3

(51) Int. Cl. H01L 31/0224; H01L 31/18

(52) U.S. Cl. 136/256; 438/73; 257/E31.124

(57) ABSTRACT

A method for producing solar cells with back side contacting, which is based on a microstructuring of a wafer provided with a dielectric layer and a doping of the microstructured regions on the back side and also an emitter diffusion on the front side. Subsequently, the deposition of a metal-containing nucleation layer and also a galvanic reinforcement of the contactings on the back side is effected. Solar cells which can be produced in accordance with the foregoing method.

The invention relates to a method for producing solar cells with back side contacting, which is based on a microstructuring of a wafer provided with a dielectric layer and a doping of the microstructured regions on the back side and also an emitter diffusion on the back side. Subsequently, the deposition of a metal-containing nucleation layer and also a galvanic reinforcement of the contactings on the back side is effected. The invention relates likewise to solar cells which can be produced in this way.

In the case of the back side contact solar cell (subsequently termed RSK cell), both the emitter and the base of the cell are contacted via the back side of the cell. This type of cell has no front side contacts. In this way, the shading losses which are caused by front side contacts in standard cells are reduced.

To date, there is only one single company in the marketplace which produces and sells RSK cells commercially. Many details for the actual manufacture of this type of cell have to date not been published. The data produced in the following are based on internal company data and procedures at the Fraunhofer ISE.

The selective doping of the RSK cell before application of the metal contacts takes place in a plurality of partly very complex, wet-chemical steps.

In the first step, a passivation layer is deposited on the substrate which generally involves an n-doped material, e.g. by means of a high-temperature step in a tube furnace, such as in the case of SiO₂ as passivation layer, or in a CVD process, as in the case of silicon nitride SiNₓ.

In the second step, an etching mask is applied on the passivation layer, either with the help of the screen printing or inkjet printing process. The etching mask comprises windows at those places at which a selective doping of the silicon on the substrate is intended to be effected later.

In the third step, those regions of the passivation layer which are left free from the etching mask are opened with the help of an etching agent, e.g. hydrofluoric acid in the case of SiO₂ as passivation material.

In the fourth step, the etching mask is removed with the help of suitable solvents.

In the fifth step, the surface is sprayed over the entire area with boron tribromide BBr₃. At increased temperature, it decomposes in the presence of residual moisture to form hydrogen bromide HBᵣ and boric acid B(OH)₃, a securely adhering borosilicate glass forming in the case of the latter compound with the bare silicon. With further heating at temperatures about approx. 1,000° C. and more, boron atoms diffuse out of said borosilicate glass into the silicon substrate and form a highly p-doped region (p⁺) there.

After completion of the high-temperature step, the remains of the borosilicate glass must be removed again by chemical etching in a sixth partial step.

The highly doped regions serve later as contact points for the metal contacts, the damaging diffusion of the metal into the semiconductor being prevented by them but the contact resistance being reduced at the same time.

In the case of the RSK cell, also the second sort of contacts is applied on the back side. These metal contacts also require highly doped regions at the contact points to the silicon substrate but this time with an N⁺ doping which is produced by phosphorus atoms.

The production of these highly doped regions is effected according to the same plan as the p⁺ doping, i.e. it comprises the same partial steps:

1. whole-area application of a passivation layer,
2. application of etching masks on the passivation layer,
3. opening of the passivation layer,
4. removal of the etching mask,
5. formation of a phosphorus silicate glass from which phosphorus diffuses into the silicon at high temperatures; phosphoryl chloride POCl₃ serves here as phosphorus source,
6. removal of the phosphorus silicate glass after the high-temperature step.

If both highly doped regions are produced on the back side, the cell is contacted. A metal, generally aluminium, is thereby evaporation coated over the whole area. Both terminals of the cell are separated from each other by selective etching off of the regions between the contact fingers with the help of etching masks.

The arrangement of both sorts of contact fingers in an RSK cell is represented in the following illustration.

The production of solar cells is associated with a large number of process steps for precision machining of wafers. There are included herein inter alia emitter diffusion, application of a dielectric layer and also microstructuring thereof, doping of the wafer, contacting, application of a nucleation layer and also thickening thereof.

A previously known gentle possibility of opening the passivation layer locally resides in applying photolithography combined with wet-chemical etching processes. Firstly a photoresist layer is thereby applied on the wafer and this is structured via UV exposure and development. There follows a wet-chemical etching step in a hydrofluoric acid-containing or phosphoric acid-containing chemical system which removes the SiNₓ at the places at which the photoresist was opened. A great disadvantage of this process is the enormous complexity and costs associated therewith. In addition, sufficient throughput for the solar cell production cannot be achieved with this method. In the case of some nitrides, in addition the process described here cannot be applied since the etching rates are too low.

It is known furthermore from the state of the art for example to remove a passivation layer made of SiNₓ by purely thermal ablation with the help of a laser beam (dry laser ablation).

With respect to the doping of the wafers, in microelectronics local doping by photolithographic structuring of a grown SiO₂ mask with subsequent whole-area diffusion in a diffusion furnace is state of the art. The metallisation is achieved by evaporation coating on a photolithographically defined resist mask with subsequent solution of the resist in organic solvents. This process has the disadvantage of having very great complexity, high time and cost requirement and also whole-area heating of the component which can possibly change further diffusion layers present and also can impair the electronic quality of the substrate.

Local doping can also be effected via screen printing of a self-doping (e.g. aluminium-containing) metal paste with subsequent drying and firing at temperatures about 900° C. The disadvantage of this process is the high mechanical loading of the component, the expensive consumables and also the high temperatures to which the entire component is subjected. Furthermore, only structural widths>100 μm are possible herewith.

A further process (“buried base contact”) uses a whole-area SiNₓ layer, opens this locally by means of laser radiation and then diffuses the doping layer in the diffusion furnace. Protected by the passivation layer, a highly doped zone is formed only in the laser-opened regions. The metallisation is formed after the back-etching of the resulting phosphorus silicate glass (PSG) by current-free deposition in a metal-containing liquid. The disadvantage of this process is the damage introduced by the laser and also the required etching step for removing the PSG. In addition, the process consists of several individual steps which make many handling steps necessary.

Starting herefrom, it was the object of the present invention to provide a more efficient method for producing solar cells, in which the number of process steps can be reduced and expensive lithography steps can essentially be dispensed with. Likewise, a reduction in the quantities of metal used for the contacting should be sought.

This object is achieved by the method having the features of claim 1 and the solar cell produced accordingly having the features of claim 16. The further dependent claims reveal advantage developments.

According to the invention, a method for producing solar cells contacted on the back side is provided, in which
a) at least the back side of a wafer is coated at least in regions with at least one dielectric layer,
b) a microstructuring of the at least one dielectric layer is effected,
c) simultaneously, an emitter diffusion at least in regions on the back side of the wafer and a doping of the microstructured surface regions on the wafer back side is effected by at least one liquid jet which is directed towards the surfaces of the wafer and comprises at least one doping agent being guided over regions of the surface to be treated, the surface being heated locally by a laser beam in advance or simultaneously,
d) a metal-containing nucleation layer is deposited at least in regions on the back side of the wafer and
e) a galvanic reinforcement at least in regions of a metallisation on the back side of the wafer is effected for two-terminal contacting thereof.

It is preferred that the microstructuring is effected by treatment of the surface with a dry laser or a water jet-guided laser or a liquid jet-guided laser comprising an etching agent. The use of a liquid jet-guided laser comprising an etching agent is thereby effected such that a liquid jet which is directed towards the surface of the wafer and comprises at least one etching agent for the wafer is guided over regions of the surface to be structured, the surface being heated locally by a laser beam in advance or simultaneously.

There is thereby selected preferably as etching agent, an agent which has a more strongly etching effect on the at least dielectric layer than on the substrate. The etching agents are selected particularly preferably from the group consisting of H₃PO₄, H₃PO₃, PCl₃, PCl₅, POCl₃, KOH, HF/HNO₃, HCl, chlorine compounds, sulphuric acid and mixtures hereof.

The liquid jet can be formed particularly preferably from pure or highly concentrated phosphoric acid or also diluted phosphoric acid. The phosphoric acid can be diluted for example in water or in another suitable solvent and can be used in different concentrations. Also additives for changing the pH value (acids or alkalis), wetting behaviour (e.g. surfactants) or viscosity (e.g. alcohols) can be added. Particularly good results are achieved when using a liquid which comprises phosphoric acid in a proportion of 50 to 85% by weight. In particular rapid processing of the surface layer can be achieved therewith out damaging the substrate and surrounding regions.

By means of the microstructuring according to the invention, two things are achieved with very low complexity.

On the one hand, the surface layer can be removed completely in the mentioned regions without the substrate thereby being damaged because the liquid on the latter has a lesser (preferably none at all) etching effect. At the same time, as a result of local heating of the surface layer in the regions to be removed, as a result of which preferably exclusively these regions are heated, a well-localised removal of the surface layer which is restricted to these regions is made possible. This results from the fact that the etching effect of the liquid typically increases with increasing temperature so that damage to the surface layer in adjacent, unheated regions as a result of parts of the etching liquid possibly reaching there is extensively avoided.

The dielectric layer which is deposited on the wafer serves for passivation and/or as antireflection layer. The dielectric layer is preferably selected from the group consisting of SiNₓ, SiO₂, SiOₓ, MgF₂, TiO₂, SiCₓ and Al₂O₃.

It is also possible that a plurality of such layers are deposited one above the other.

Preferably, the emitter diffusion and the doping is implemented in step c) with an H₃PO₄, H₃PO₃ and/or POCl₃-containing liquid jet into which a laser beam is coupled.

The doping agent is preferably selected from the group consisting of phosphorus, boron, indium, gallium and mixtures hereof, in particular phosphoric acid, phosphorous acid, solutions of phosphates and hydrogen phosphates, borax, boric acid, borates and perborates, boron compounds, gallium compounds and mixtures thereof.

A further preferred variant provides that the microstrucuring, the emitter diffusion and the boron doping are implemented simultaneously with a liquid jet-guided laser.

A further variant according to the invention comprises a doping of the microstructured silicon wafer and simultaneously the emitter diffusion on the back side of the wafer being effected during the precision processing subsequent to the microstructuring and the liquid jet comprising a doping agent.

This can be achieved by using a liquid which comprises at least one compound which etches the solid body material instead of the liquid containing at least one doping agent. This variant is particularly preferred since firstly the microstructuring and, by the exchange of liquids, subsequently the doping can be implemented in the same device. Alternatively, the microstructuring can also be implemented by means of an aerosol jet, laser radiation not being absolutely required in this variant since comparable results can be achieved by heating the aerosol or the components thereof in advance.

The method according to the invention, preferably for microstructuring and doping and also the emitter diffusion, uses a technical system in which a liquid jet, which can be equipped with various chemical systems, serves as liquid light guide for a laser beam. The laser beam is coupled into the liquid jet via a special coupling device and guided by internal total reflection. In this way, a supply of chemicals and laser beam to the process hearth at the same time and place is guaranteed. The laser light thereby assumes different tasks: on the one hand is able to heat the substrate surface locally at the impingement point thereof, optionally thereby to melt it and in the extreme case to evaporate it. As a result of contemporaneous impingement of chemicals on the heated substrate surface, chemical processes which do not take place under standard conditions because they are kinetically restricted or are unfavourable from a thermodynamic point of view can be activated. In addition to the thermal effect of the laser light, also a photochemical activation is possible with respect to the laser light generating for example electron hole pairs on the surface of the substrate, which electron hole pairs can promote the course of redox reactions in this region or make it possible at all.

The liquid jet also ensures, in addition to focusing the laser beam and the chemical supply, cooling of the edge-positioned regions of the process hearth and rapid transport away of the reaction products. The last-mentioned aspect is an important prerequisite for promoting and accelerating rapidly evolving chemical (equilibrium) processes. The cooling of the edge-positioned regions which are not involved in the reaction and above all are not subject to the material removal can be protected by the cooling effect of the jet from thermal stresses and crystalline damage resulting therefrom, which enables a low-damage or damage-free structuring of the solar cells. Furthermore, the liquid jet endows the supplied materials, because of its high flow velocity, with a significant mechanical impetus which is particularly effective when the jet impinges on a molten substrate surface.

Laser beam and liquid jet together form a new process tool which is superior in its combination in principle to the individual systems of which it consists.

The metal-containing nucleation layer is preferably deposited by evaporation coating, sputtering or by reduction from aqueous solution. The metal-containing nucleation layer thereby comprises preferably a metal from the group aluminium, nickel, titanium, chromium, tungsten, silver and alloys thereof.

After application of the nucleation layer, this is preferably treated thermally, e.g. by laser annealing.

After application of the metal-containing nucleation layer, preferably a thickening of the nucleation layer at least in regions is effected by galvanic deposition of a metallisation, in particular of silver or copper, as a result of which contacting of the back side of the wafer is effected.

Preferably, as laminar a liquid jet as possible is used for implementing the method. The laser beam can then be guided in a particularly effective manner by total reflection in the liquid jet so that the latter fulfils the function of a light guide. The coupling of the laser beam can be effected, for example through a window which is orientated perpendicular to a beam direction of the liquid jet, in a nozzle unit. The window can thereby be configured as a lens for focusing the laser beam. Alternatively or additionally, also a lens which is independent of the window can be used for focusing or forming the laser beam.

The nozzle unit can thereby be designed in a particularly simple embodiment of the invention such that the liquid is supplied from one side or a plurality of sides in the direction radial to the jet direction.

There are preferred as usable types of laser:

various solid body lasers, in particular the commercially frequently used Nd-YAG laser of the wavelength 1,064 nm, 532 nm, 355 nm, 266 nm and 213 nm, diode lasers with wavelengths<1,000 nm, argon-ion lasers of the wavelength 514 to 458 nm Excimer lasers (wavelengths: 157 to 351 nm).

The tendency is for the quality of the microstructuring to increase with reducing wavelengths because the energy induced by the laser in the surface layer thereby increasingly is concentrated better and better on the surface, which tends to reduce the heat influence zone and, associated therewith, to reduce the crystalline damage in the material, above all in the phosphorus-doped silicon below the passivation layer.

In this context, blue lasers and lasers in the near UV range (e.g. 355 nm) with pulsed lengths in the femtosecond to nanosecond range have proved to be particularly effective. By using in particular short-wave laser light, the option exists furthermore of direct generation of electron/hole pairs in the silicon which can be used for the electrochemical process during nickel deposition (photochemical activation). Thus free electrons in the silicon generated for example by laser light can contribute, in addition to the above already described redox process of the nickel ions with phosphorous acid, which was already described above, directly to the reduction of nickel on the surface. This electron/hole generation can be maintained permanently by permanent illumination of the sample with defined wavelengths (in particular in the near UV with λ≦355 nm) during the structuring process and can promote the metal nucleation process in a sustained manner.

For this purpose, the solar cell property can be used in order to separate the excess charge carrier via the p-n junction and hence to charge the n-conducting surface negatively.

A further preferred variant of the method according to the invention provides that the laser beam is actively adjusted in temporal and/or spatial pulse form. The flat top form, an M-profile and a rectangular pulse are included herein.

According to the invention, a solar cell which can be produced according to the previously-described method is likewise provided.

The subject according to the invention is intended to be explained in more detail with reference to the subsequent FIGURE and the subsequent example without wishing to restrict said subject to the special embodiments shown here.

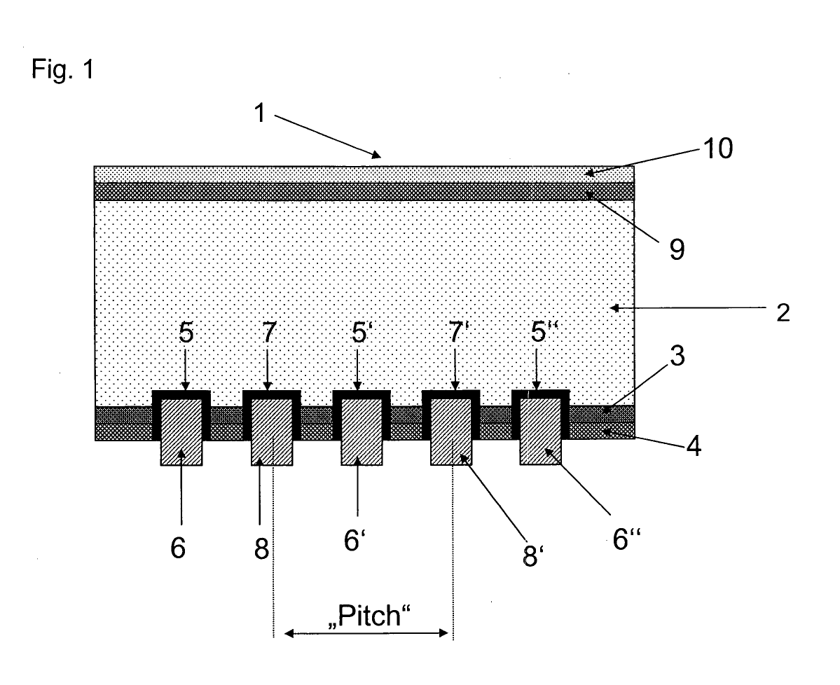

FIG. 1 shows an embodiment of the solar cell produced according to the invention.

The solar cell 1 according to the invention in FIG. 1 has a wafer on an n-silicon base 2, which is coated on the back side with an electrical field (n′ back surface field) 3. A passivation layer 4 is disposed on this layer. In defined regions on the back side of the wafer, p⁺⁺ emitters 5, 5′ and 5″ and p-metal fingers 6, 6′ and 6″ are disposed. For this purpose, regions which have electrical fields on the back side (n⁺⁺ back surface fields) 7, 7′, 7″ and n-metal fingers 8, 8′, 8″ are disposed adjacently. On the front side of the wafer 2, an n⁺ front surface field 9 and also a passivation layer 10 is disposed.

### EXAMPLE 1

A wire-sawn wafer with an n-type base doping is firstly subjected to a damage etch in order to remove the wire-saw damage, this damage etch being implemented for 20 minutes at 80° C. in 40% KOH. There follows a one-sided texturing of the wafer in 1% KOH at 98° C. (duration approx. 35 minutes). In a following step, a deposition of a front surface field (FSF) is effected on the front side of the wafer and a back surface field (BSF) on the back side of the wafer. These steps are implemented simultaneously by phosphorus diffusion in the tube furnace using POCl₃ as phosphorus source. The layer resistance of this weakly doped layer is in a range of 100 to 400 ohm/sq. Subsequently, a thin thermal oxide layer is produced in the tube furnace. The thickness of the oxide layer is hereby in a range of 6 to 15 nm. In the following process step, a PECVD deposition of silicon nitride (refractive index n=2.0 to 2.1, thickness of the layer: approx. 60 nm) is effected on the front side and back side of the wafer. The thus treated wafer is subsequently structured on the back side with the liquid jet. The formation of the selective back surface field (BSF) is hereby effected with the help of a laser which is coupled to a liquid jet (so-called laser chemical processing, LCP). 85% phosphoric acid is used as beam medium. The line width of the structures is approx. 30 μm and the spacing between the structures 1 to 3 mm. An Nd:YAG laser at 532 nm (P=7 W) is thereby used. The travel speed is 400 mm/s. A region doped in this way has a resistance of 10 to 50 ohm/sq. The formation of a local emitter on the back side is subsequently effected by means of LCP, for which purpose boric acid (c=40 g/l) is used. The line width is approx. 30 μm and the spacing between two contact fingers 1 to 3 mm. Here also, laser parameters and travel speed are identical to the two previous method steps. The layer resistance here is between 10 and 60 ohm/sq. A current-free deposition on the emitter and on the back surface field is effected subsequently for formation of a nucleation layer. A metallisation solution is hereby used, which comprises NaPH₂O₂, NiCl₂, a stabiliser, a complex former for Ni²⁺ ions, such as e.g. citric acid. The bath temperature is 90° C. Sintering of the back side contacts is effected subsequently at temperatures of 300 to 500° C. in a forming gas atmosphere (N₂H₂). Finally, a galvanic deposition of silver or copper is effected in order to thicken the front-, emitter- and base-back side contacts up to a thickness of the contacts of approx. 10 μm. For the galvanic bath, silver cyanide (c=1 mol/l) is used here as silver source. The bath temperature is 25° C., the voltage applied on the wafer back side 0.3 V.

1. A method for producing solar cells with back side contacting, in which
a) at least the back side of a wafer is coated at least in regions with at least one dielectric layer,
b) a microstructuring of the at least one dielectric layer is effected,
c) simultaneously, an emitter diffusion at least in regions or a diffusion of the back side electrical field (BSF) on the back side of the wafer and a doping of the microstructured surface regions on the wafer back side is effected by at least one liquid jet which is directed towards the surfaces of the wafer and comprises at least one doping agent being guided over regions of the surface to be treated, the surface being heated locally by a laser beam in advance or simultaneously,
d) a metal-containing nucleation layer is deposited at least in regions on the back side of the wafer and
e) a galvanic deposition at least in regions of a metallisation on the back side of the wafer is effected for back side contacting thereof.

2. The method according to claim 1,
wherein the microstructuring is effected by treatment of the surface with a dry laser or a water jet-guided laser or a liquid jet-guided laser comprising an etching agent, by a liquid jet which is directed towards the surface of the solid body and comprises at least one etching agent for the wafer being guided over regions of the surface to be structured, the surface being heated locally by a laser beam in advance or simultaneously.

3. The method according to claim 1, wherein the etching agent has a more strongly etching effect on the at least dielectric layer than on the substrate and is selected from the group consisting of H₃PO₄, H₃PO₃, PCl₃, PCl₅, POCl₃, KOH, HF/HNO₃, HCl, chlorine compounds, sulphuric acid and mixtures hereof.

4. The method according to claim 1, wherein the dielectric layer is selected from the group consisting of SiNₓ, SiO₂, SiOₓ, MgF₂, TiO₂, SiCₓ and Al₂O₃.

5. The method according to claim 1, wherein the emitter diffusion and the doping of the back side electrical field is implemented with an H₃PO₄, H₃PO₃ and/or POCl₃-containing liquid jet into which a laser beam is coupled.

6. The method according to claim 1, wherein the at least one doping agent is selected from the group consisting of phosphorus, boron, aluminium, indium, gallium and mixtures hereof.

7. The method according to claim 1, wherein the microstructuring, the doping of the back side electrical field and the emitter diffusion are implemented simultaneously with a liquid jet-guided laser.

8. The method according to claim 1, wherein the metal-containing nucleation layer is deposited by evaporation coating, sputtering or by reduction from an aqueous solution.

9. The method according to claim 1, wherein the metal-containing nucleation layer comprises a metal from the group aluminium, nickel, titanium, chromium, tungsten, silver and alloys thereof.

10. The method according to claim 1, wherein, after application of the nucleation layer, this is treated thermally, in particular by laser annealing.

11. The method according to claim 1, wherein, after application of the metal-containing nucleation layer, a thickening of the nucleation layer at least in regions is effected by galvanic deposition of a metallisation by silver or copper, as a result of which thickening of the emitter- and base metal grid is effected.

12. The method according to claim 1, wherein the laser beam is guided by total reflection in the liquid jet.

13. The method according to claim 1, wherein the liquid jet is laminar.

14. The method according to claim 1, wherein the liquid jet has a diameter of 10 to 500 μm.

15. The method according to claim 1, wherein the laser beam is actively adjusted in temporal and/or spatial pulse form.

16. A solar cell produced according to the method claim 1.

17. The method according to claim 1, wherein the at least one doping agent is selected from phosphoric acid, phosphorous acid, solutions of phosphates and hydrogen phosphates, borax, boric acid, borates and perborates, boron compounds, gallium compounds and mixtures thereof.

18. The method according to claim 15, wherein the laser beam is actively adjusted in flat top form, M-profile or rectangular pulse
